(19) United States
(12) Patent Application Publication
(10) Pub. No.: US 2014/0167103 A1
(43) Pub. Date: Jun. 19, 2014

(54) SEMICONDUCTOR DEVICE AND METHOD OF MANUFACTURING THE SAME

(71) Applicant: Samsung Electro-Mechanics Co., Ltd., Suwon (KR)

(72) Inventors: Jaehoon Park, Suwon (KR); Inhyuk Song, Suwon (KR); Dongsoo Seo, Suwon (KR); Kwangsoo Kim, Suwon (KR); Keeju Um, Suwon (KR)

(73) Assignee: Samsung Electro-Mechanics Co., Ltd., Suwon (KR)

(21) Appl. No.: 14/049,992

(22) Filed: Oct. 9, 2013

(30) Foreign Application Priority Data
Dec. 13, 2012 (KR) 10-2012-0145301
Apr. 16, 2013 (KR) 10-2013-0041599

(51) Int. Cl. H01L 29/739; H01L 29/66

(52) U.S. Cl. CPC H01L 29/7397; H01L 29/66348
USPC 257/139; 438/138

(57) ABSTRACT

Disclosed herein is a semiconductor device including a semiconductor substrate, a collector layer formed under the semiconductor substrate, a base layer formed on the semiconductor substrate, an emitter layer formed on the base layer, one or more trench barriers vertically penetrating the base layer and the emitter layer, a first gate insulating layer formed on the trench barriers and the emitter layer such that an upper portion of the emitter layer is partially exposed, a gate formed on the first gate insulating layer, a second gate insulating layer formed to cover the gate, and an emitter metal layer formed on an upper portion of the emitter layer exposed by the first gate insulating layer.

### CROSS REFERENCE TO RELATED APPLICATION

This application claims the benefit of Korean Patent Application No. 10-2012-0145301, filed Dec. 13, 2012, entitled “Semiconductor Device and Method of Manufacturing the Same”, and Korean Patent Application No. 10-2013-0041599, filed Apr. 16, 2013, entitled “Semiconductor Device and Method of Manufacturing the Same”, which are hereby incorporated by reference in their entireties into this application.

### BACKGROUND OF THE INVENTION

1. Technical Field

The present invention relates to a semiconductor device and a method of manufacturing the same.

2. Description of the Related Art

Demand for small power transmission devices such as inverters used in robots, air-conditioners, machine tools, and the like, or industrial electronics represented by uninterruptible power equipment is rapidly on the rise. As application coverage of power transmission devices has increased, compactness, a light weight, high efficiency, and low noise of power transmission devices have increasingly come into consideration. However, conventional power semiconductor devices such as a bipolar transistor, a high power metal oxide semiconductor field effect transistor (MOSFET), and the like, have difficulty in satisfying the requirements. Thus, an insulated gate bipolar transistor (IGBT) having both the high speed switching characteristics of the high power MOSFET and high power characteristics of a bipolar transistor has come to prominence as a semiconductor device (U.S. Pat. No. 6,503,786).

### SUMMARY OF THE INVENTION

The present invention has been made in an effort to provide a semiconductor device having increased current density, and a method of manufacturing the same.

The present invention has been made in an effort to provide a semiconductor device that generates less loss by inducing an additional ON voltage, and a method of manufacturing the same.

According to an embodiment of the present invention, there is provided a semiconductor device including: a semiconductor substrate; a collector layer formed under the semiconductor substrate; a base layer formed on the semiconductor substrate; an emitter layer formed on the base layer; one or more trench barriers vertically penetrating the base layer and the emitter layer; a first gate insulating layer formed on the trench barriers and the emitter layer such that an upper portion of the emitter layer is partially exposed; a gate formed on the first gate insulating layer; a second gate insulating layer formed to cover the gate; and an emitter metal layer formed on an upper portion of the emitter layer exposed by the first gate insulating layer.

The trench barrier may include a central portion vertically penetrating the base layer and the emitter layer, a first trench insulating layer formed on the base layer and the emitter layer and surrounding the central portion, and a second trench insulating layer formed on an upper portion of the central portion.

The semiconductor substrate may be an n-type semiconductor substrate.

The first gate insulating layer and the second gate insulating layer may be formed to include at least one of a silicon insulating layer, SiON, GexOyNz, and a high dielectric material.

The first trench insulating layer may be formed to include at least one of a silicon dioxide film, SiON, GexOyNz, and a high dielectric material.

The second trench insulating layer may be formed to include at least one of borophosphosilicate glass (BPSG) and tetraethylorthosilicate (TEOS).

The central portion may be made of polysilicon.

The trench barrier may be formed to include at least one of a silicon dioxide film, SiON, GexOyNz, and a high dielectric material.

The base layer may include a p-type low concentration impurity.

The emitter layer may include an n-type high concentration impurity.

The collector layer may include a p-type high concentration impurity.

The base layer and the emitter layer may be formed in lower portions at both sides of the gate, respectively.

The trench barrier may be formed to extend from the emitter layer formed in one side of the gate to the emitter layer formed in the other side of the gate.

According to another embodiment of the present invention, there is provided a method of manufacturing a semiconductor device, including: preparing a semiconductor substrate; forming one or more trench barriers on the semiconductor substrate; forming a base layer on the semiconductor substrate; forming an emitter layer on the base layer; forming a first gate insulating layer on the trench barrier and the emitter layer; forming a gate on the first gate insulating layer; forming a second gate insulating layer covering the gate; patterning the first gate insulating layer such that an upper portion of the emitter layer is partially exposed; forming an emitter metal layer on the emitter layer exposed by the first gate insulating layer; and forming a collector layer under the semiconductor substrate.

The semiconductor substrate may be an n-type semiconductor substrate.

The forming of the trench barrier may include: etching the semiconductor substrate to form a trench penetrating the base layer and the emitter layer; forming a first trench insulating layer within the trench; burying the interior of the trench with polysilicon; and forming a second trench insulating layer on the polysilicon and the semiconductor substrate.

The first trench insulating layer may be formed to include at least one of a silicon dioxide film, SiON, GexOyNz, and a high dielectric material.

The second trench insulating layer may be formed to include at least one of borophosphosilicate glass (BPSG) and tetraethylorthosilicate (TEOS).

The forming of the trench barrier may include: etching the semiconductor substrate to form a trench; and forming a trench insulating layer within the trench and on the semiconductor substrate.

The trench barrier may be formed to include at least one of a silicon dioxide film, SiON, GexOyNz, and a high dielectric material.

In the forming of the base layer, the base layer may be formed by injecting a p-type low concentration impurity into the semiconductor substrate.

In the forming of the emitter layer, the emitter layer may be formed by injecting an n-type high concentration impurity into the base layer.

In the forming of the gate on the first gate insulating layer, the gate may be formed with polysilicon.

The first gate insulating layer and the second gate insulating layer may be formed to include at least one of a silicon insulating layer, SiON, GexOyNz, and a high dielectric material.

A plurality of the trench barriers may be formed.

In the forming of the collector layer, the collector layer may be formed by injecting a p-type high concentration impurity.

The base layer and the emitter layer may be formed in lower portions at both sides of the gate, respectively.

The trench barrier may be formed to extend from the emitter layer formed in one side of the gate to the emitter layer formed in the other side of the gate.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is an exemplified diagram illustrating a semiconductor device according to an embodiment of the present invention;

FIGS. 2 through 14 are exemplified diagrams illustrating a method of manufacturing a semiconductor device according to an embodiment of the present invention;

FIG. 15 is an exemplified diagram illustrating a semiconductor device according to another embodiment of the present invention; and

FIGS. 16 through 28 are exemplified diagrams illustrating a method of manufacturing a semiconductor device according to another embodiment of the present invention.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like, are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Semiconductor Device

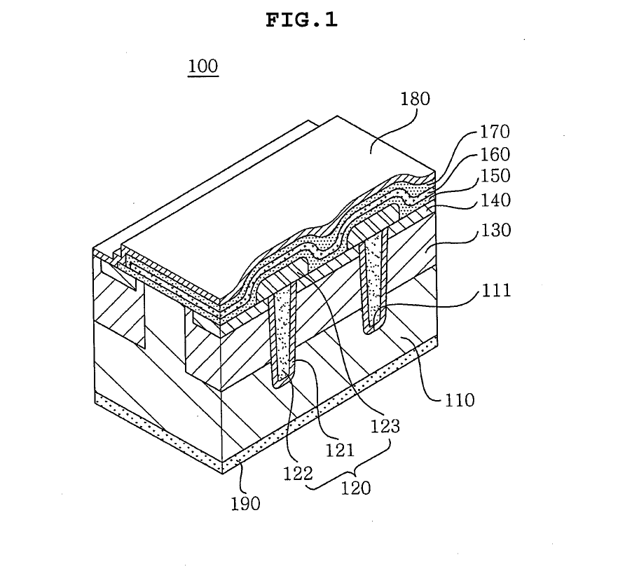

FIG. 1 is an exemplified diagram illustrating a semiconductor device according to an embodiment of the present invention.

A semiconductor device 100 according to an embodiment of the present invention may include a semiconductor substrate 110, a collector layer 190, a base layer 130, an emitter layer 140, a trench barrier 120, a first gate insulating layer 150, a gate 160, a second gate insulating layer 170, and an emitter metal layer 180.

The semiconductor substrate 110 may be an N-type semiconductor substrate. Namely, the semiconductor substrate 110 may be a semiconductor substrate doped with N-type impurity. Here, the N-type impurity may be a Group V element such as phosphorus (P), arsenide (As), or the like.

The collector layer 190 may be formed under the semiconductor substrate 110. The collector layer 190 may be formed by injecting a p-type high concentration impurity into the semiconductor substrate 110. For example, the p-type impurity may be boron (B), boron fluoride (BF2, BF3), indium (In), or the like.

The base layer 130 may be formed on the semiconductor substrate 110. The base layer 130 may be formed by injecting a p-type low concentration impurity into the semiconductor substrate 110.

The emitter layer 140 may be formed on the base layer 130. The emitter layer 140 may be formed by injecting an N-type high concentration impurity into the base layer 130. Here, the emitter layer 140 may be formed to be adjacent to an upper surface of the semiconductor substrate 110.

The trench barrier 120 may be formed to vertically penetrate the base layer 130 and the emitter layer 140. According to an embodiment of the present invention, one or more trench barriers 120 may be formed. The plurality of trench barriers 120 may be arranged in a length direction.

The trench barrier 120 may include a central portion 122, a first trench insulating layer 121, and a second trench insulating layer 123. The central portion 122 may be formed to vertically penetrate the base layer 130 and the emitter layer 140. Due to the trench barrier 120, a path along which holes injected from the collector layer 190 move to the base layer 130 and the emitter layer 140 may be narrowed. Thus, since the hole movement path is narrowed, holes are accumulated in a lower portion of the trench barrier 120, and conductivity modulation occurs, increasing a current density.

The central portion 122 may be made of polysilicon. The first trench insulating layer 121 may be formed in the base layer 130 and the emitter layer 140 and surround the central portion 122. The first trench insulating layer 121 may be formed to include at least one of a silicon dioxide film, SiON, GexOyNz, and a high dielectric material. The second trench insulating layer 123 may be formed in an upper portion of the central portion 122. In an embodiment of the present invention, the second trench insulating layer 123 may be formed to cover even a portion of the emitter layer 140, as well as the upper portion of the central portion 122, and have a predetermined thickness. However, the structure of the second trench insulating layer 123 is not limited thereto. The second trench insulating layer 123 may be modified in design to have any structure as long as it can insulate the central portion 122 with the outside of the trench barrier 120. The second trench insulating layer 123 may be formed to include at least one of borophosphosilicate glass (BPSG) and tetraethylorthosilicate (TEOS).

In an embodiment of the present invention, the trench barrier 120 includes the central portion 122, the first trench insulating layer 121, and the second trench insulating layer 123, but the present invention is not limited thereto. For example, the central portion 122, the first trench insulating layer 121, and the second trench insulating layer 123 of the trench barrier 120 may have an integrated structure and may be made of the same insulating material. Here, the trench barrier 120 may be formed to include at least one of a silicon dioxide film, SiON, GexOyNz, and a high dielectric material.

The first gate insulating layer 150 may be formed on the trench barrier 120 and the emitter layer 140. Here, the first gate insulating layer 150 may be formed to allow an upper portion of the emitter layer 140 to be partially exposed.

The gate 160 may be formed on the first gate insulating layer 150. The gate 160 may be made of polysilicon.

The second gate insulating layer 170 may be formed to cover the gate 160. The first gate insulating layer 150 and the second gate insulating layer 170 may be formed to include at least one of a silicon dioxide film, SiON, GexOyNz, and a high dielectric material.

The emitter metal layer 180 may be formed on an upper portion of the emitter layer 140 exposed by the first gate insulating layer 150. Being in contact with the emitter layer 140, the emitter metal layer 180 may be electrically connected to the emitter layer 140.

For the description purpose, FIG. 1 illustrates a cross-section of the semiconductor device 100 in which a plurality of trench barriers 120 are arranged.

Also, although not shown, it would be obvious by a person skilled in the art that both sides of the semiconductor device 100 are symmetrical on the basis of the gate 160. Namely, the structure of the other side of the gate 160 (not shown) is symmetrical to the structure including the base layer 130, the emitter layer 140, the first gate insulating layer 150, the second gate insulating layer 170, and the emitter metal layer 180 formed in one side thereof.

Method of Manufacturing Semiconductor Device

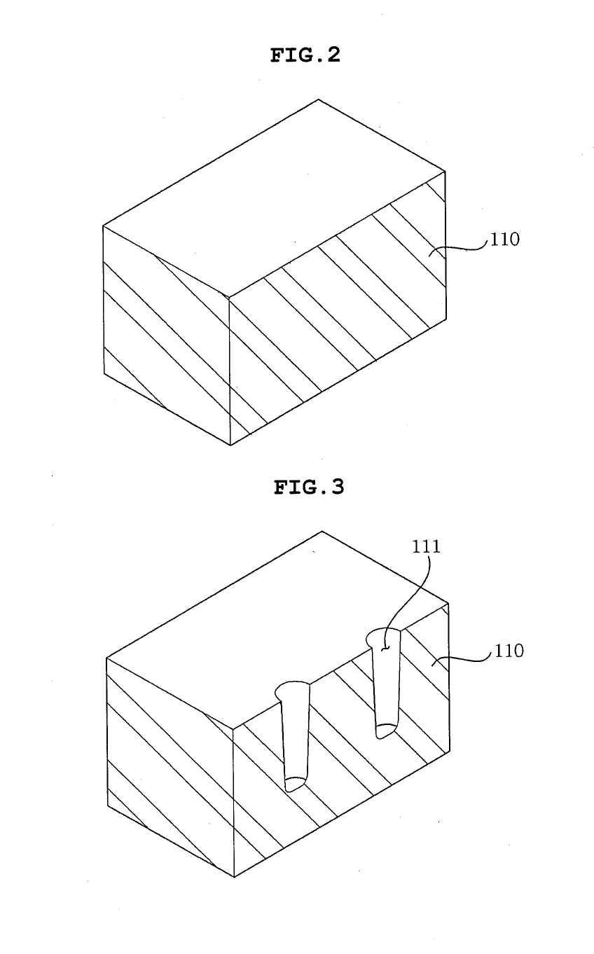

FIGS. 2 through 14 are exemplified diagrams illustrating a method of manufacturing a semiconductor device according to an embodiment of the present invention.

Referring to FIG. 2, a semiconductor substrate 110 is provided. The semiconductor substrate 110 may be an N-type semiconductor substrate. Namely, the semiconductor substrate 110 may be a semiconductor substrate with N-type impurity doped therein. Here, the N-type impurity may be a Group V element such as phosphorous (P), arsenide (As), or the like.

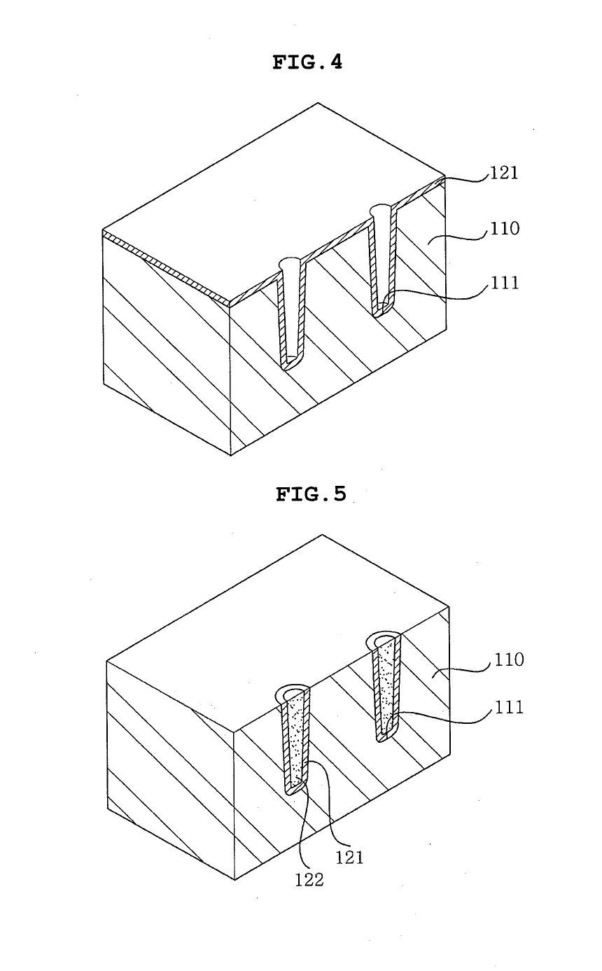

Referring to FIG. 3, a trench 111 may be formed in the semiconductor substrate 110. First, a trench mask (not shown) may be formed on an upper portion of the semiconductor substrate 110. The trench mask (not shown) is a mask for forming the trench 111. The trench mask (not shown) may be patterned such that a region in which the trench 111 is to be formed is opened. The trench mask (not shown) is positioned in an upper portion of the semiconductor substrate 110, photolithography may be performed to form the trench 111. Here, the trench 111 may be formed to have a depth penetrating the base layer 130 and the emitter layer 140 which are formed later. After the formation of the trench 111, the trench mask (not shown) may be removed. In the present embodiment, two trenches 111 are formed, but the present invention is not limited thereto. Namely, the number of trenches 111 is not limited and may be changed according to the need of a person skilled in the art. In the present embodiment, two trenches 111 are formed for the description purpose.

Referring to FIG. 4, the first trench insulating layer 121 may be formed. The first trench insulating layer 121 may be formed on an upper portion of the semiconductor substrate 110 and on an inner wall of the trench 111. The first trench insulating layer 121 may be formed by using chemical vapor deposition (CVD). For example, the first trench insulating layer 121 may be a silicon dioxide film, SiON, GexOyNz, a high dielectric material, or a combination thereof, or a laminated film formed by sequentially laminating them. The high dielectric material may be HfO₂, ZrO₂, Al₂O₃, Ta₂O₅, hafnium silicate, zirconium silicate, or a combination thereof.

Referring to FIG. 5, the central portion 122 may be formed within the trench 111 on which the first trench insulating layer 121 is formed. Namely, the interior of the trench 111 with the first trench insulating layer 121 formed thereon may be buried with polysilicon. Also, the polysilicon may be formed to have a predetermined thickness on the first trench insulating layer 121 and the trench 111. Thereafter, except for polysilicon burying the trench 111, the other remaining polysilicon may be removed. The polysilicon burying the interior of the trench 111 formed thusly may be the central portion 122 of the trench barrier 120. The removing of the polysilicon may be performed through an etch back or wet etching process.

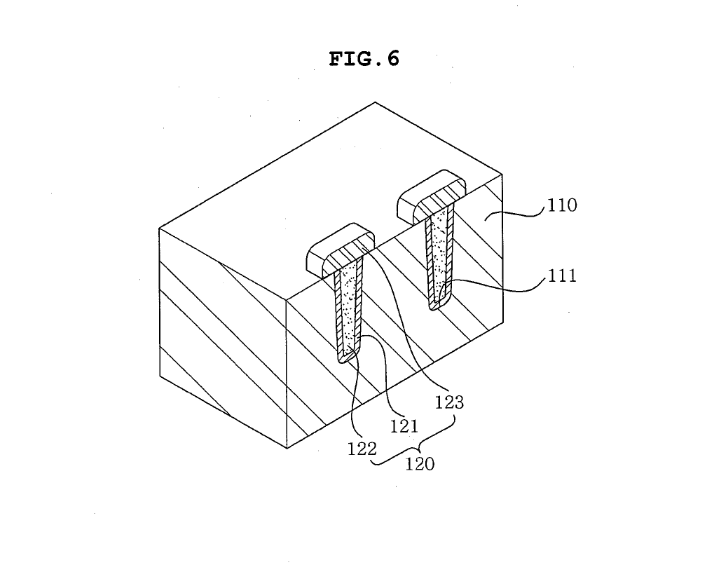

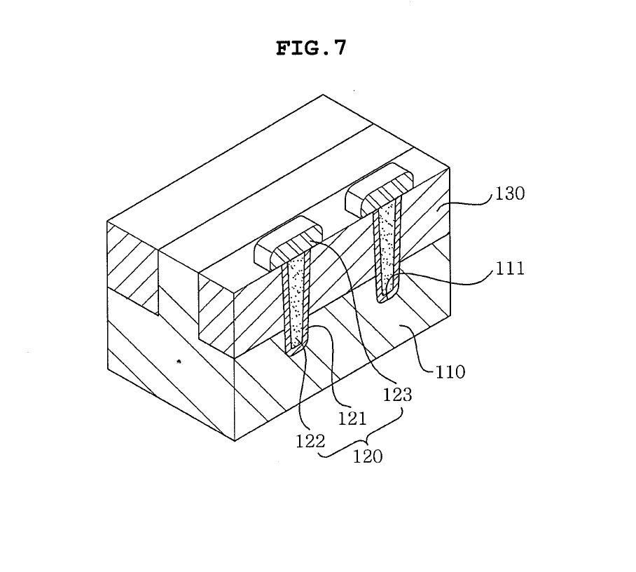

Referring to FIG. 6, the second trench insulating layer 123 may be formed. Here, the second trench insulating layer 123 may be formed at an upper portion of the central portion 122. The second trench insulating layers 123 formed at upper portions of the plurality of central portions 122 may be spaced apart from each other. For example, the second trench insulating layer 123 may be made of borophosphosilicate glass (BPSG). Alternatively, the second trench insulating layer 123 may be made of tetraethylorthosilicate (TEOS) as an organic material.

In this manner, as the first trench insulating layer 121, the central portion 122, and the second trench insulating layer 123 are formed, the trench barrier 120 may be formed.

In the present embodiment, the trench barrier 120 may include the first trench insulating layer 121, the central portion 122, and the second trench insulating layer 123, but the present invention is not limited thereto. For example, the trench barrier 120 may include only the first trench insulating layer 121. Namely, the trench barrier 120 may be formed by burying the interior of the trench 111 with the first trench insulating layer 121. In this manner, the structure and material of the trench barrier 120 may be easily modified in design by a person skilled in the art as long as the trench barrier may be able to insulate the interior and the exterior of the trench 111.

Referring to FIG. 7, the base layer 130 may be formed. The base layer 130 may be formed on the semiconductor substrate 110. The base layer 130 may be formed by injecting a p-type low concentration impurity into the semiconductor substrate 110. For example, the p-type impurity may be boron (B), boron fluoride (BF2, BF3), indium (In), or the like.

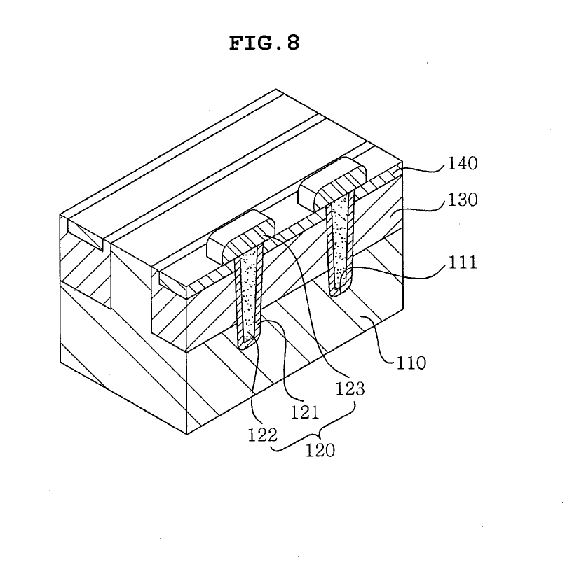

Referring to FIG. 8, the emitter layer 140 may be formed. The emitter layer 140 may be formed by injecting an n-type high concentration impurity into the base layer 130. Here, the emitter layer 140 may be formed to be adjacent to an upper surface of the semiconductor substrate 110 formed on an upper portion of the base layer 130.

After the formation of the base layer 130 and the emitter layer 140, a reflow may be performed.

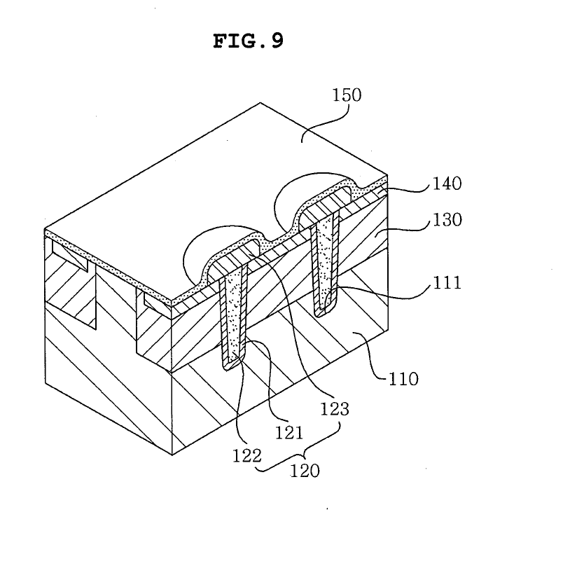

Referring to FIG. 9, the first gate insulating layer 150 may be formed. The first gate insulating layer 150 may be formed on the entire upper surface of the semiconductor substrate 110. Namely, the first gate insulating layer 150 may be formed on upper portions of the emitter layer 140, the base layer 130, and the second trench insulating layer 123. The first gate insulating layer 150 may be formed by using chemical vapor deposition (CVD). For example, the first gate insulating layer 150 may be a silicon dioxide film, SiON, GexOyNz, a high dielectric material, or a combination thereof, or may be a laminated film formed by sequentially laminating them. The high dielectric material may be HfO₂, ZrO₂, Al₂O₃, Ta₂O₅, hafnium silicate, zirconium silicate, or a combination thereof.

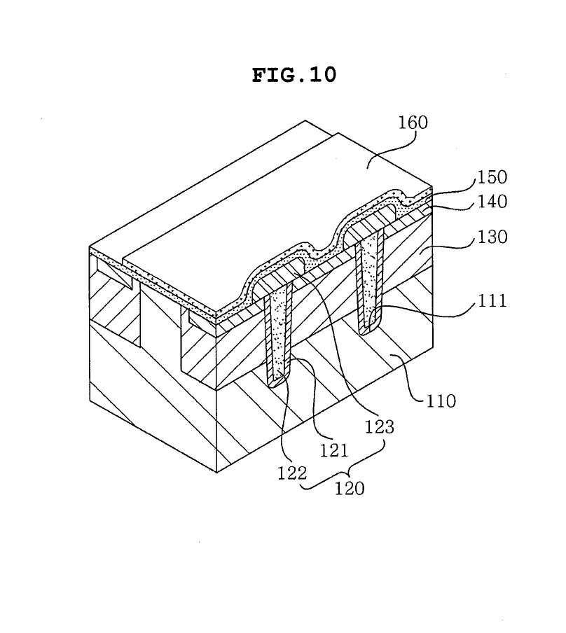

Referring to FIG. 10, the gate 160 may be formed. The gate 160 may be formed on an upper portion of the first gate insulating layer 150. Also, the gate 160 may be formed such that a portion of the first gate insulating layer 150 formed on the emitter layer 140 is exposed. The gate 160 may be made of polysilicon.

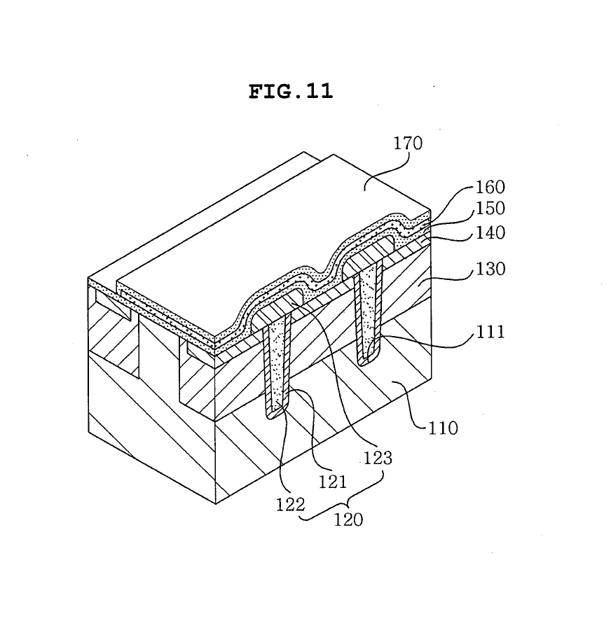

Referring to FIG. 11, the second gate insulating layer 170 may be formed. The second gate insulating layer 170 may be formed to cover the gate 160. The second gate insulating layer 170 may be made of the same material as that of the first gate insulating layer 150.

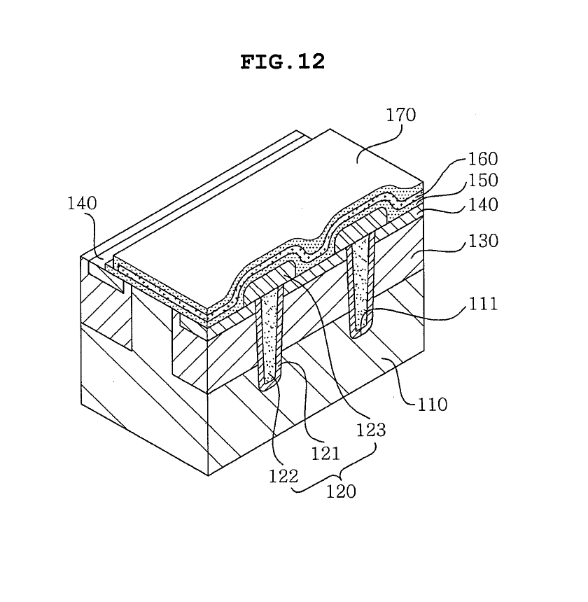

Referring to FIG. 12, patterning may be performed for a connection of the emitter metal layer 180. Here, a portion of the first gate insulating layer 150 formed on an upper portion of the emitter layer 140 may be removed to expose a portion of the emitter layer 140.

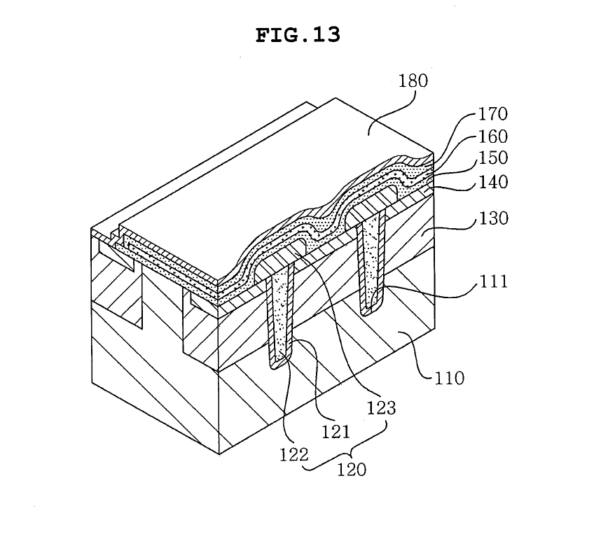

Referring to FIG. 13, the emitter metal layer 180 may be formed. The emitter metal layer 180 may be formed on upper portions of the first gate insulating layer 150, the second gate insulating layer 170, and the exposed emitter layer 140. The emitter metal layer 180 formed thusly may be electrically in contact with the exposed emitter layer 140.

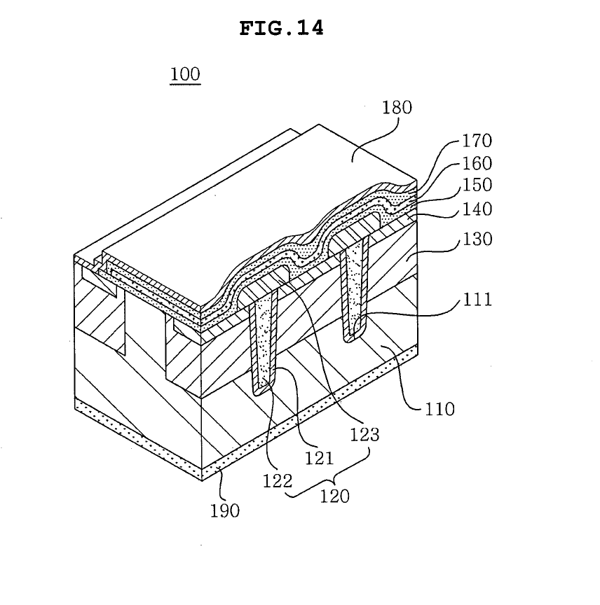

Referring to FIG. 14, the collector layer 190 may be formed. The collector layer 190 may be formed under the semiconductor substrate 110. The collector layer 190 may be formed by injecting a p-type high concentration impurity.

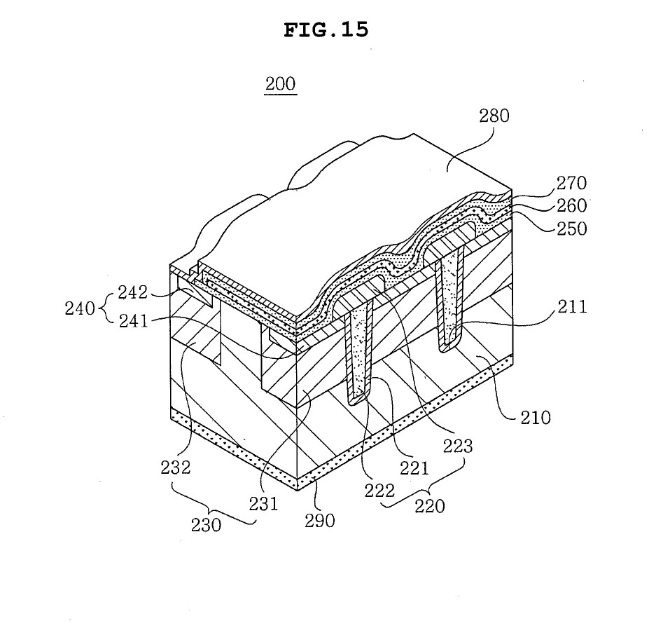

FIG. 15 is an exemplified diagram illustrating a semiconductor device according to another embodiment of the present invention.

A semiconductor device 200 according to an embodiment of the present invention may include a semiconductor substrate 210, a collector layer 290, a base layer 230, an emitter layer 240, a trench barrier 220, a first gate insulating layer 250, a gate 260, a second gate insulating layer 270, and an emitter metal layer 280.

The semiconductor substrate 210 may be an N-type semiconductor substrate. Namely, the semiconductor substrate 210 may be a semiconductor substrate doped with N-type impurity. Here, the N-type impurity may be a Group V element such as phosphorus (P), arsenide (As), or the like.

The collector layer 290 may be formed under the semiconductor substrate 210. The collector layer 290 may be formed by injecting a p-type high concentration impurity into the semiconductor substrate 210. For example, the p-type impurity may be boron (B), boron fluoride (BF2, BF3), indium (In), or the like.

The base layer 230 may be formed on the semiconductor substrate 210. The base layer 230 may be formed by injecting a p-type low concentration impurity into the semiconductor substrate 210.

The emitter layer 240 may be formed on the base layer 230. The emitter layer 240 may be formed by injecting an N-type high concentration impurity into the base layer 230. Here, the emitter layer 240 may be formed to be adjacent to an upper surface of the semiconductor substrate 210.

The base layer 230 and the emitter layer 240 may be formed in lower portions at both sides of the gate 260, respectively.

The trench barrier 220 may be formed to vertically penetrate the base layer 230 and the emitter layer 240. According to an embodiment of the present invention, one or more trench barriers 220 may be formed. The plurality of trench barriers 220 may be arranged in a length direction. The trench barrier 220 may be formed to extend from one side of the semiconductor substrate 210 to the other side thereof. The trench barrier 220 formed as illustrated in FIG. 15 may further narrow a movement path of holes, relative to that of the trench barrier 120 formed in a lower portion at one side of the gate (160 in FIG. 1), increasing current density more effectively.

The trench barrier 220 may include a central portion 222, a first trench insulating layer 221, and a second trench insulating layer 223. The central portion 222 may be formed to vertically penetrate the base layer 230 and the emitter layer 240. Also, the central portion 222 may be formed extending from one side of the semiconductor substrate 210 to the other side thereof. The central portion 222 may be made of polysilicon. The first trench insulating layer 221 may be formed in the base layer 230 and the emitter layer 240 and surround the central portion 222. The first trench insulating layer 221 may be formed to include at least one of a silicon dioxide film, SiON, GexOyNz, and a high dielectric material. The second trench insulating layer 223 may be formed in an upper portion of the central portion 222. In an embodiment of the present invention, the second trench insulating layer 223 may be formed to cover even portions of the emitter layer 240 and the base layer 230, as well as the upper portion of the central portion 222, and have a predetermined thickness. However, the structure of the second trench insulating layer 223 is not limited thereto. The second trench insulating layer 223 may be modified in design to have any structure as long as it can insulate the central portion 222 with the outside of the trench barrier 220. The second trench insulating layer 223 may be formed to include at least one of borophosphosilicate glass (BPSG) and tetraethylorthosilicate (TEOS).

In an embodiment of the present invention, the trench barrier 220 includes the central portion 222, the first trench insulating layer 221, and the second trench insulating layer 223, but the present invention is not limited thereto. For example, the central portion 222, the first trench insulating layer 221, and the second trench insulating layer 223 of the trench barrier 220 may have an integrated structure and may be made of the same insulating material. Here, the trench barrier 220 may include at least one of a silicon dioxide film, SiON, GexOyNz, and a high dielectric material.

The first gate insulating layer 250 may be formed on the trench barrier 220 and the emitter layer 240. Here, the first gate insulating layer 250 may be formed to allow an upper portion of the emitter layer 240 to be partially exposed.

The gate 260 may be formed on the first gate insulating layer 250. The gate 260 may be made of polysilicon.

The second gate insulating layer 270 may be formed to cover the gate 260. The first gate insulating layer 250 and the second gate insulating layer 270 may be formed to include at least one of a silicon insulating film, SiON, GexOyNz, and a high dielectric material.

The emitter metal layer 280 may be formed in an upper portion of the trench barrier 220 and may be formed on an upper portion of the emitter layer 240 exposed by the first gate insulating layer 250. Being in contact with the emitter layer 240, the emitter metal layer 280 may be electrically connected to the emitter layer 240.

For the description purpose, FIG. 15 illustrates a cross-section of the semiconductor device 200 in which a plurality of trench barriers 220 are arranged.

Also, although not shown, it would be obvious by a person skilled in the art that both sides of the semiconductor device 200 are symmetrical on the basis of the gate 260. Namely, the structure of the other side of the gate 260 (not shown) is formed to be symmetrical to the structure including the base layer 230, the emitter layer 240, the first gate insulating layer 250, the second gate insulating layer 270, and the emitter metal layer 280 formed in one side thereof.

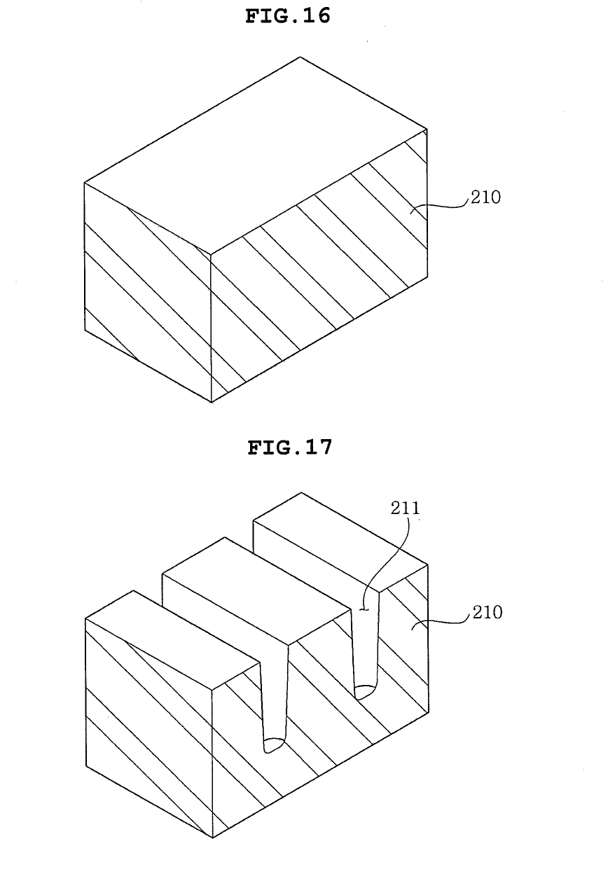

FIGS. 16 through 28 are exemplified diagrams illustrating a method of manufacturing a semiconductor device according to an embodiment of the present invention.

Referring to FIG. 16, a semiconductor substrate 210 is provided. The semiconductor substrate 210 may be an N-type semiconductor substrate. Namely, the semiconductor substrate 210 may be a semiconductor substrate with N-type impurity doped therein. Here, the N-type impurity may be a Group V element such as phosphorous (P), arsenide (As), or the like.

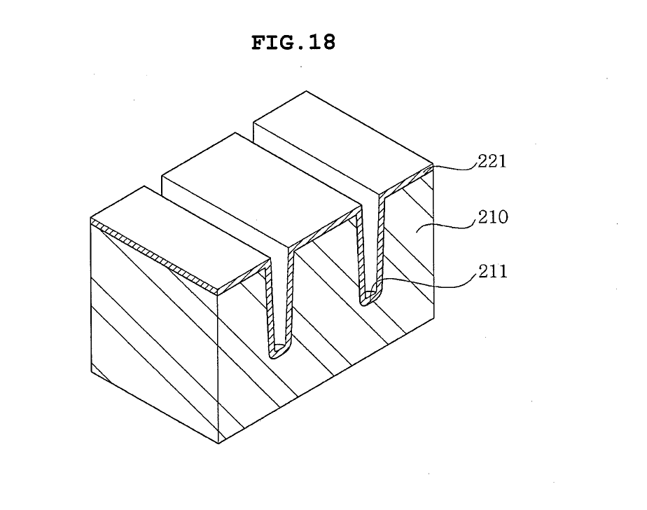

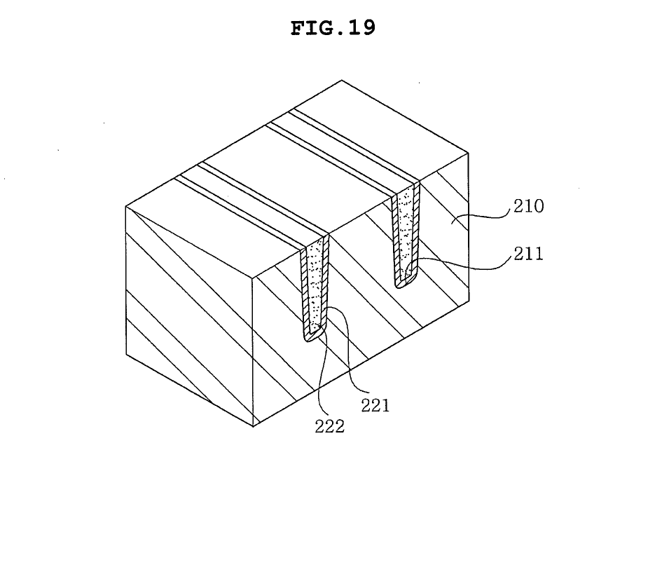

Referring to FIG. 17, a trench 211 may be formed in the semiconductor substrate 210. First, a trench mask (not shown) may be formed on an upper portion of the semiconductor substrate 210. The trench mask (not shown) is a mask for forming the trench 211. The trench mask (not shown) may be patterned such that a region in which the trench 211 is to be formed is opened. The trench mask (not shown) is positioned in an upper portion of the semiconductor substrate 210, photolithography may be performed to form the trench 211. Here, the trench 211 may be formed to have a depth penetrating the base layer 230 and the emitter layer 240. Also, as illustrated in FIG. 17, the trench 211 may be formed to extend from one side of the semiconductor substrate 210 to the other side thereof. After the formation of the trench 211, the trench mask (not shown) may be removed. In the present embodiment, two trenches 211 are formed, but the present invention is not limited thereto. Namely, the number of trenches 211 is not limited and may be changed according to the need of a person skilled in the art. In the present embodiment, two trenches 211 are formed for the description purpose.

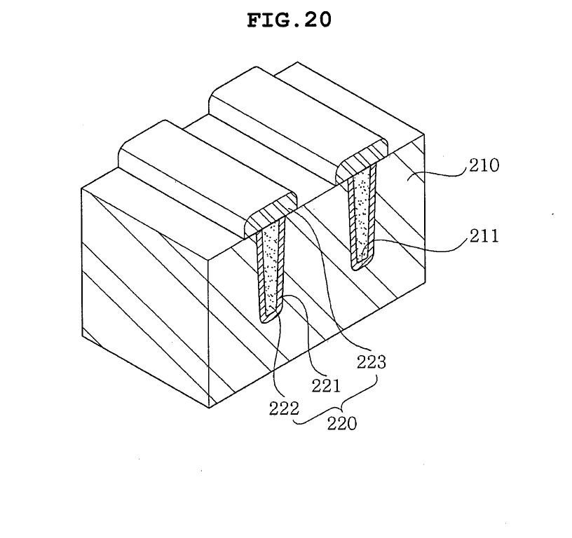

Referring to FIG. 18, the first trench insulating layer 221 may be formed. The first trench insulating layer 221 may be formed on an upper portion of the semiconductor substrate 210 and on an inner wall of the trench 211. The first trench insulating layer 221 may be formed by using chemical vapor deposition (CVD). For example, the first trench insulating layer 221 may be a silicon dioxide film, SiON, GexOyNz, a high dielectric material, or a combination thereof, or a laminated film formed by sequentially laminating them. The high dielectric material may be HfO₂, ZrO₂, Al₂O₃, Ta₂O₅, hafnium silicate, zirconium silicate, or a combination thereof.

Referring to FIG. 19, the central portion 222 may be formed within the trench 211 on which the first trench insulating layer 221 is formed. Namely, the interior of the trench 211 with the first trench insulating layer 221 formed thereon may be buried with polysilicon. Also, the polysilicon may be formed to have a predetermined thickness on the first trench insulating layer 221 and the trench 211. Thereafter, except for polysilicon burying the trench 211, the other remaining polysilicon may be removed. The polysilicon burying the interior of the trench 211 formed thusly may be the central portion 222 of the trench barrier 220. The removing of the polysilicon may be performed through an etch back or wet etching process.

Referring to FIG. 20, the second trench insulating layer 223 may be formed. Here, the second trench insulating layer 223 may be formed at an upper portion of the central portion 222. The second trench insulating layers 223 formed at upper portions of the plurality of central portions 222 may be spaced apart from each other. For example, the second trench insulating layer 223 may be made of borophosphosilicate glass (BPSG). Alternatively, the second trench insulating layer 223 may be made of tetraethylorthosilicate (TEOS) as an organic material.

In this manner, as the first trench insulating layer 221, the central portion 222, and the second trench insulating layer 223 are formed, the trench barrier 220 may be formed.

In the present embodiment, the trench barrier 220 may include the first trench insulating layer 221, the central portion 222, and the second trench insulating layer 223, but the present invention is not limited thereto. For example, the trench barrier 220 may include only the first trench insulating layer 221. Namely, the trench barrier 220 may be formed by burying the interior of the trench 211 with the first trench insulating layer 221. In this manner, the structure and material of the trench barrier 220 may be easily modified in design by a person skilled in the art as long as the trench barrier 220 may be able to insulate the interior and the exterior of the trench 211.

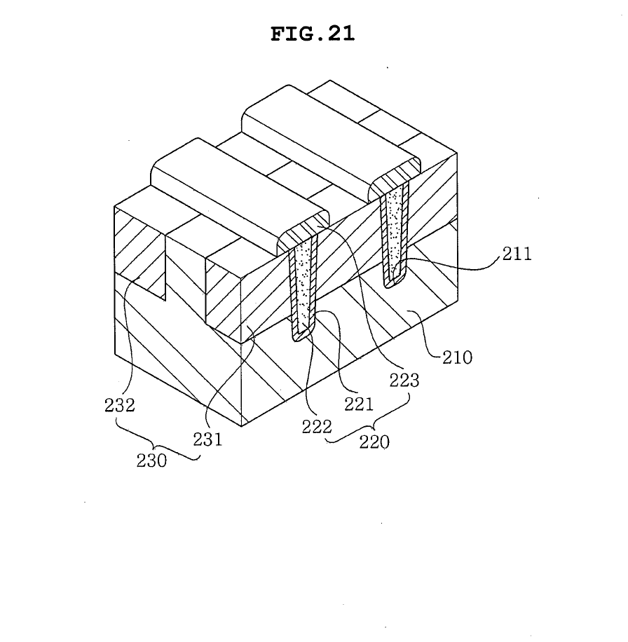

Referring to FIG. 21, the base layer 230 may be formed. The base layer 230 may be formed on the semiconductor substrate 210. The base layer 230 may be formed by injecting a p-type low concentration impurity into the semiconductor substrate 210. For example, the p-type impurity may be boron (B), boron fluoride (BF2, BF3), indium (In), or the like. The base layer 230 may include a first base layer 231 and a second base layer 232. Also, the first base layer 231 and the second base layer 232 may be formed to be spaced from one another.

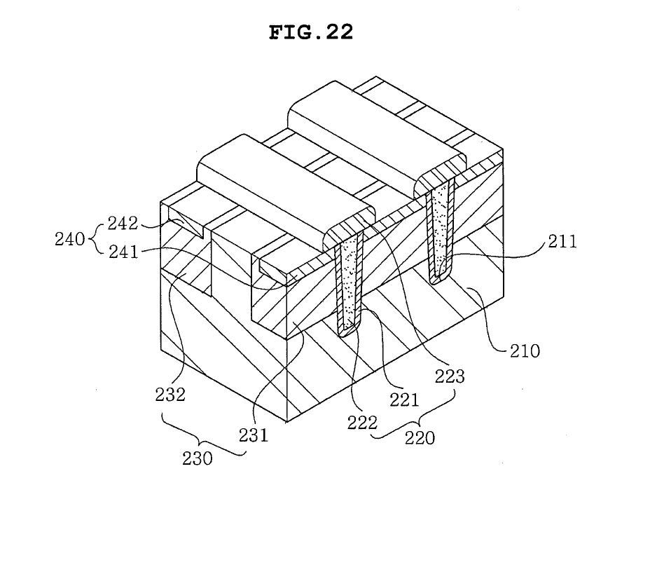

Referring to FIG. 22, the emitter layer 240 may be formed. The emitter layer 240 may be formed by injecting an n-type high concentration impurity into the base layer 230. Here, the emitter layer 240 may be formed to be adjacent to an upper surface of the semiconductor substrate 210 formed on an upper portion of the base layer 230. The emitter layer 240 may include a first emitter layer 241 and a second emitter layer 242. The first emitter layer 241 may be formed within the first base layer 231. Also, the second emitter layer 242 may be formed within the second base layer 232.

After the formation of the base layer 230 and the emitter layer 240, a reflow may be performed.

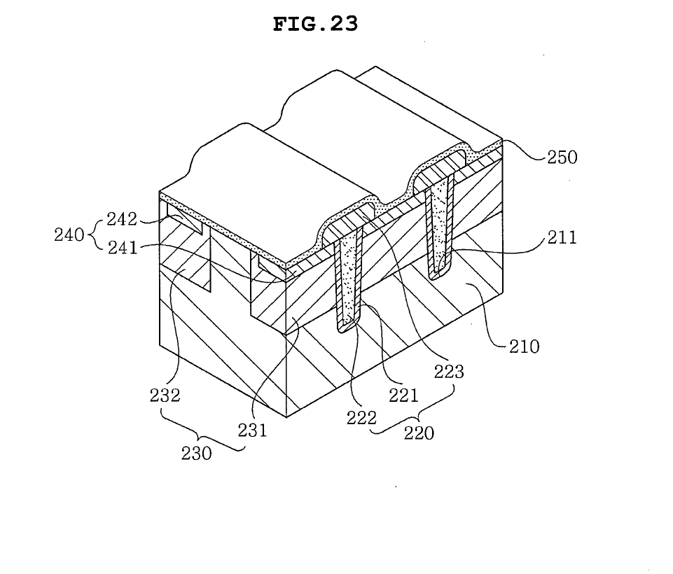

Referring to FIG. 23, the first gate insulating layer 250 may be formed. The first gate insulating layer 250 may be formed on the entire upper surface of the semiconductor substrate 210. Namely, the first gate insulating layer 250 may be formed on upper portions of the emitter layer 240, the base layer 230, and the second trench insulating layer 223. The first gate insulating layer 250 may be formed by using chemical vapor deposition (CVD). For example, the first gate insulating layer 250 may be a silicon dioxide film, SiON, GexOyNz, a high dielectric material, or a combination thereof, or may be a laminated film formed by sequentially laminating them. The high dielectric material may be HfO₂, ZrO₂, Al₂O₃, Ta₂O₅, hafnium silicate, zirconium silicate, or a combination thereof.

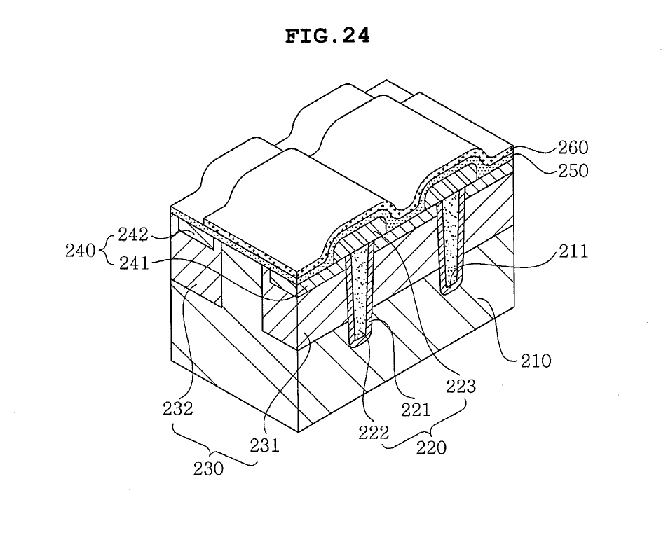

Referring to FIG. 24, the gate 260 may be formed. The gate 260 may be formed on an upper portion of the gate insulating layer 250. Also, the gate 260 may be formed such that a portion of the first gate insulating layer 250 formed on the emitter layer 240 is exposed. The gate 260 may be made of polysilicon.

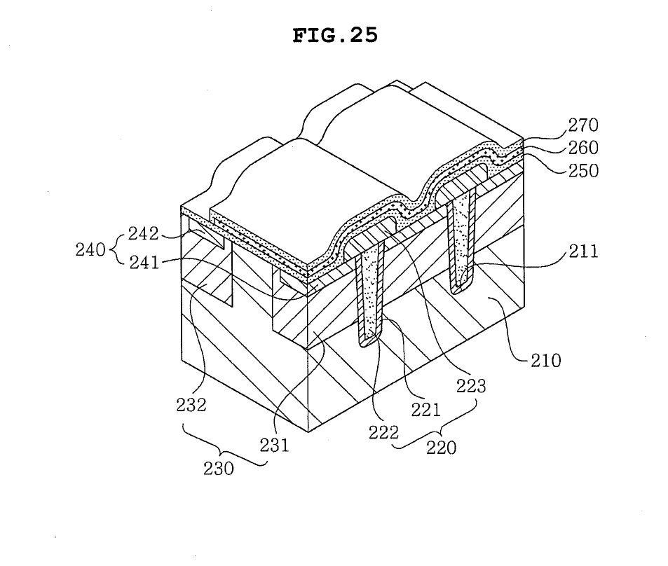

Referring to FIG. 25, the second gate insulating layer 270 may be formed. The second gate insulating layer 270 may be formed to cover a lateral surface and an upper surface of the gate 260. Here, a portion of the first gate insulating layer 250 may be exposed by the second gate insulating layer 270. The first gate insulating layer 250 exposed by the second gate insulating layer 270 may be formed in an upper portion of the emitter layer 240. The second gate insulating layer 270 may be made of the same material as that of the first gate insulating layer 250.

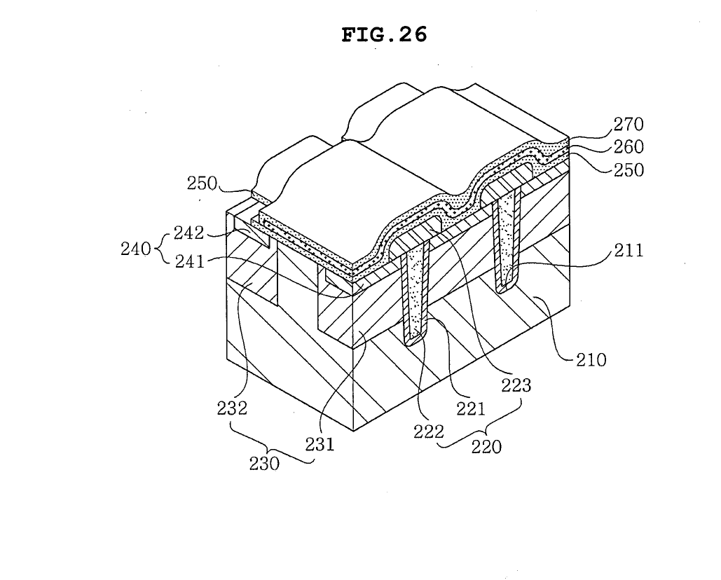

Referring to FIG. 26, patterning may be performed for a connection of the emitter metal layer 280. A portion of the first gate insulating layer 250 formed in an upper portion of the emitter layer 240 may be patterned. The patterning of the first gate insulating layer 250 may be performed by removing the first gate insulating layer 250 exposed by the second gate insulating layer 250. In this manner, the removal of the first gate insulating layer 250 exposes a portion of the emitter layer 240 to the outside. Also, the removal of the first gate insulating layer 250 may expose the second trench insulating layer 223 of the trench barrier 220 to the outside. Namely, whether the second trench insulating layer 223 is exposed may be determined according to a patterning configuration of the first gate insulating layer 250.

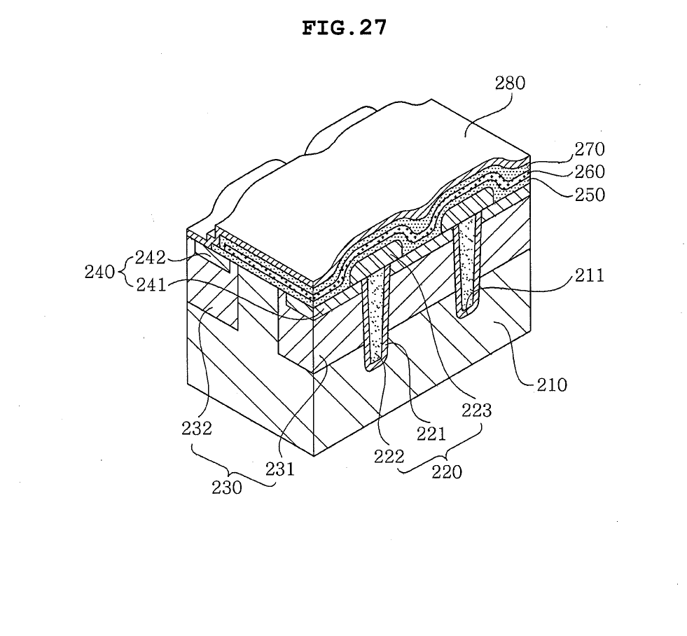

Referring to FIG. 27, the emitter metal layer 280 may be formed. The emitter metal layer 280 may be formed in upper portions of the first gate insulating layer 250, the second gate insulating layer 270, and the exposed emitter layer 240. Also, when the second trench insulating layer 223 is exposed, the emitter metal layer 280 may also be formed in an upper portion of the second trench insulating layer 223. The emitter metal layer 280 formed thusly may be electrically in contact with the exposed emitter layer 240.

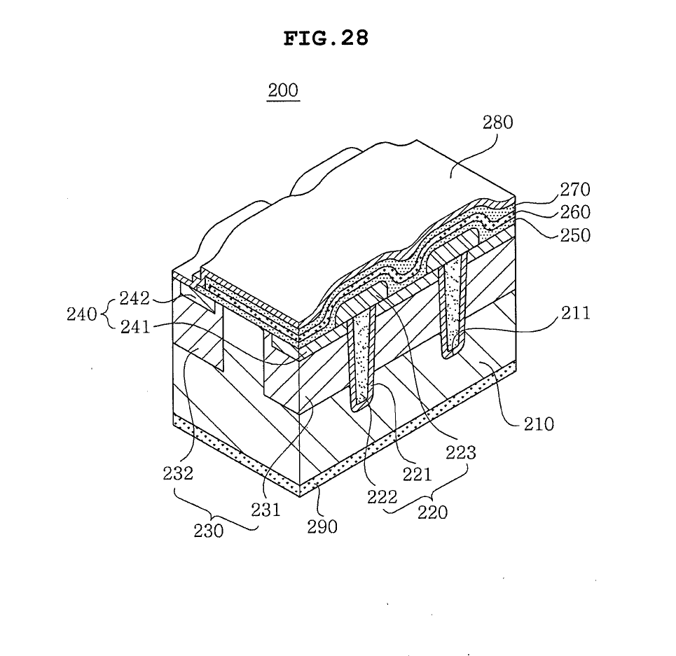

Referring to FIG. 28, the collector layer 290 may be formed. The collector layer 290 may be formed under the semiconductor substrate 210. The collector layer 290 may be formed by injecting a p-type high concentration impurity.

The semiconductor device according to an embodiment of the present invention may be a planar gate type IGBT. Also, the semiconductor device may have a trench barrier penetrating through the trench emitter layer and the base layer. Also, the trench barrier may be formed to extend from the first emitter layer to the second emitter layer. Due to the presence of the trench barrier, a movement path of holes injected from the collector layer is narrowed, and thus, holes are accumulated in a lower portion of the trench barrier. As the holes are accumulated in the lower portion of the trench barrier, conductivity modulation may occur. Namely, the accumulation of holes reduces resistance, and thus, a current density between the collector layer and the emitter layer may be increased.

In this manner, the semiconductor device according to an embodiment of the present invention has the advantages of a planar gate type IGBT and reduces loss by inducing an additional ON voltage by increasing a current density.

In the case of the semiconductor device and the method of manufacturing the same according to embodiments of the present invention, since the trench barrier is formed, a current density can be increased.

In the case of the semiconductor device and the method of manufacturing the same according to embodiments of the present invention, since the current density is increased, an additional ON voltage can be induced, reducing loss.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A semiconductor device comprising:
a semiconductor substrate;
a collector layer formed under the semiconductor substrate;
a base layer formed on the semiconductor substrate;
an emitter layer formed on the base layer; one or more trench barriers vertically penetrating the base layer and the emitter layer;
a first gate insulating layer formed on the trench barriers and the emitter layer such that an upper portion of the emitter layer is partially exposed;
a gate formed on the first gate insulating layer;
a second gate insulating layer formed to cover the gate; and
an emitter metal layer formed on an upper portion of the emitter layer exposed by the first gate insulating layer.

2. The semiconductor device as set forth in claim 1, wherein the trench barrier includes a central portion vertically penetrating the base layer and the emitter layer, a first trench insulating layer formed on the base layer and the emitter layer and surrounding the central portion, and a second trench insulating layer formed on an upper portion of the central portion.

3. The semiconductor device as set forth in claim 1, wherein the semiconductor substrate is an n-type semiconductor substrate.

4. The semiconductor device as set forth in claim 1, wherein the first gate insulating layer and the second gate insulating layer are formed to include at least one of a silicon insulating layer, SiON, GexOyNz, and a high dielectric material.

5. The semiconductor device as set forth in claim 2, wherein the first trench insulating layer is formed to include at least one of a silicon dioxide film, SiON, GexOyNz, and a high dielectric material.

6. The semiconductor device as set forth in claim 2, wherein the second trench insulating layer is formed to include at least one of borophosphosilicate glass (BPSG) and tetraethylorthosilicate (TEOS).

7. The semiconductor device as set forth in claim 2, wherein the central portion is made of polysilicon.

8. The semiconductor device as set forth in claim 1, wherein the trench barrier is formed to include at least one of a silicon dioxide film, SiON, GexOyNz, and a high dielectric material.

9. The semiconductor device as set forth in claim 1, wherein the base layer includes a p-type low concentration impurity.

10. The semiconductor device as set forth in claim 1, wherein the emitter layer includes an n-type high concentration impurity.

11. The semiconductor device as set forth in claim 1, wherein the collector layer includes a p-type high concentration impurity.

12. The semiconductor device as set forth in claim 1, wherein the base layer and the emitter layer are formed in lower portions at both sides of the gate, respectively.

13. The semiconductor device as set forth in claim 12, wherein the trench barrier are formed to extend from the emitter layer formed in one side of the gate to the emitter layer formed in the other side of the gate.

14. A method of manufacturing a semiconductor device, the method comprising:
preparing a semiconductor substrate;
forming one or more trench barriers on the semiconductor substrate;
forming a base layer on the semiconductor substrate;
forming an emitter layer on the base layer;
forming a first gate insulating layer on the trench barrier and the emitter layer;
forming a gate on the first gate insulating layer;
forming a second gate insulating layer covering the gate;
patterning the first gate insulating layer such that an upper portion of the emitter layer is partially exposed;
forming an emitter metal layer on the emitter layer exposed by the first gate insulating layer; and
forming a collector layer under the semiconductor substrate.

15. The method as set forth in claim 14, wherein the semiconductor substrate is an n-type semiconductor substrate.

16. The method as set forth in claim 14, wherein the forming of the trench barrier comprises:
etching the semiconductor substrate to form a trench penetrating the base layer and the emitter layer;
forming a first trench insulating layer within the trench;
burying the interior of the trench with polysilicon; and
forming a second trench insulating layer on the polysilicon and the semiconductor substrate.

17. The method as set forth in claim 16, wherein the first trench insulating layer is formed to include at least one of a silicon dioxide film, SiON, GexOyNz, and a high dielectric material.

18. The method as set forth in claim 16, wherein the second trench insulating layer is formed to include at least one of borophosphosilicate glass (BPSG) and tetraethylorthosilicate (TEOS).

19. The method as set forth in claim 14, wherein the forming of the trench barrier comprises:
etching the semiconductor substrate to form a trench; and
forming a trench insulating layer within the trench and on the semiconductor substrate.

20. The method as set forth in claim 19, wherein the trench barrier is formed to include at least one of a silicon dioxide film, SiON, GexOyNz, and a high dielectric material.

21. The method as set forth in claim 14, wherein in the forming of the base layer,
the base layer is formed by injecting a p-type low concentration impurity into the semiconductor substrate.

22. The method as set forth in claim 14, wherein in the forming of the emitter layer, the emitter layer is formed by injecting an n-type high concentration impurity into the base layer.

23. The method as set forth in claim 14, wherein in the forming of the gate on the first gate insulating layer, the gate is formed with polysilicon.

24. The method as set forth in claim 14, wherein the first gate insulating layer and the second gate insulating layer are formed to include at least one of a silicon insulating layer, SiON, GexOyNz, and a high dielectric material.

25. The method as set forth in claim 14, wherein a plurality of trench barriers are formed.

26. The method as set forth in claim 14, wherein in the forming of the collector layer, the collector layer is formed by injecting a p-type high concentration impurity.

27. The method as set forth in claim 14, wherein the base layer and the emitter layer are formed in lower portions at both sides of the gate, respectively.

28. The method as set forth in claim 27, wherein the trench barrier are formed to extend from the emitter layer formed in one side of the gate to the emitter layer formed in the other side of the gate.
